(19) United States
(12) Patent Application Publication
(10) Pub. No.: US 2021/0083157 A1
(43) Pub. Date: Mar. 18, 2021

(54) Optoelectronic Component and Method for Producing an Optoelectronic Component

(71) Applicant: OSRAM OLED GmbH, Regensburg (DE)

(72) Inventors: Rebecca Römer, Regensburg (DE); Thomas Reeswinkel, Regensburg (DE)

(21) Appl. No.: 16/978,143

(22) PCT Filed: Mar. 20, 2019
(86) PCT No.: PCT/EP2019/056968

§ 371 Date: Sep. 3, 2020

(30) Foreign Application Priority Data
Mar. 21, 2018 (DE) 102018106695.3

(51) Int. Cl. H01L 33/58; H01L 33/50

(52) U.S. Cl. CPC H01L 33/58; H01L 2933/0058; H01L 33/507

(57) ABSTRACT

An optoelectronic component and a method for producing an optoelectronic component are disclosed. In an embodiment, an optoelectronic component includes a semiconductor chip configured to emit radiation and moisture-stable glass particles arranged in a beam path of the semiconductor chip, wherein the moisture-stable glass particles are filler, scattering particles and/or filter particles, wherein each of the moisture-stable glass particles comprises a moisture-sensitive core of a glass material, and wherein the core is covered with at least one moisture-stable inorganic coating.

This patent application is a national phase filing under section 371 of PCT/EP2019/056968, filed Mar. 20, 2019, which claims the priority of German patent application 102018106695.3, filed Mar. 21, 2018, each of which is incorporated herein by reference in its entirety.

### TECHNICAL FIELD

The invention relates to an optoelectronic component. Furthermore, the invention relates to a process for producing an optoelectronic component.

### BACKGROUND

Conversion elements, which in particular have phosphors embedded in silicone as matrix material, often reach their limits with respect to temperature stability. There are different ways to increase the temperature stability of conversion elements, for example, by transferring from a volume conversion element to a layer conversion element. The main reason for the degradation of the conversion element is often insufficient heat dissipation in the conversion layer, because the matrix material, especially silicone, has a low thermal conductivity of about 0.1 W/mK and ages rapidly due to heat. The use of a conversion layer leads to a decrease in the matrix portion, especially the silicone portion, of the conversion element, and the thermal conductivity rises above the phosphor portion (for example silicone with phosphor with a thermal conductivity of up to 0.3 W/mK). At the same time, the phosphor can be brought close to the semiconductor chip surface (heat sink). However, the methods described here are only suitable to a limited extent for an optoelectronic component with a high CCT value (low phosphor content), because in such a component the chip is only insufficiently covered with phosphor and therefore there is an increased emergence of blue light on the exposed flanks of the semiconductor chip and thus an intensely inhomogeneous color impression of the optoelectronic component arises from different viewing angles (“blue piping”). Furthermore, the temperature stability is not sufficiently improved for all applications and CCTs (components with high red portion in the spectrum and warm white color locations suffer more from overheating than components with a low red portion in the spectrum and cold white color locations).

Conversion elements with high thermal conductivity are therefore required. This task can be achieved by increasing the thermal conductivity by adding transparent conductive fillers to the conversion element. Such fillers can be glass or other transparent particles with a thermal conductivity higher than that of the matrix material of the conversion element. For example, if the matrix material is silicone (about 0.1 W/mK), then a-quartz (6.8-12 W/mK), fused silica (˜1.4 W/mK), sapphire (30 W/mK), calcium fluoride (9-10 W/mK), magnesium oxide (30-60 W/mK) or a transparent silicate can be used. They can have a spherical, rod-shaped or simply their natural crystal form. The fillers can be the same, smaller or larger size as the phosphor particles in the conversion element. They can be mixed with the phosphor. Alternatively, the fillers can be introduced into the conversion element as a filler layer.

### SUMMARY

Embodiments provide an optoelectronic component which overcomes the above disadvantages and at the same time comprises moisture-stable glass particles which are stable against environmental influences. Further embodiments provide a process for the production of an optoelectronic component which produces a stable component.

In at least one embodiment, the optoelectronic component comprises a semiconductor chip. The semiconductor chip is capable of emitting radiation. The component has moisture-stable glass particles. The glass particles are arranged in the beam path of the semiconductor chip. The glass particles are used as filler, scattering particles and/or filter particles. The moisture-stable glass particles each have a moisture-sensitive core. The respective moisture-sensitive core comprises or consists of a glass material. The moisture-sensitive core is at least covered with a moisture-stable inorganic coating. The coating is in particular complete. This can provide protection against environmental influences, such as atmospheric oxygen, moisture or acid gases, such as hydrogen sulphide.

According to at least one embodiment, the optoelectronic component is a light-emitting diode, or LED for short. The optoelectronic component is preferably configured to emit yellow, blue, red, orange, green or especially white light. In particular, the optoelectronic component emits warm white light or cold white light.

According to at least one embodiment, the optoelectronic component comprises a semiconductor chip. The semiconductor chip is capable of emitting radiation. In particular, the semiconductor chip emits radiation during operation of the optoelectronic component, for example from the blue wavelength range.

According to at least one embodiment of the optoelectronic component, this comprises at least one optoelectronic semiconductor chip. The optoelectronic semiconductor chip has a semiconductor layer sequence. The semiconductor layer sequence of the semiconductor chip is preferably based on a III-V compound semiconductor material. The semiconductor material is preferably a nitride compound semiconductor material such as AlₙIn₁₋ₙ₋ₘGaₘN or also a phosphide compound semiconductor material such as AlₙIn₁₋ₙ₋ₘGaₘP, wherein respectively 0≤n≤1, 0≤m≤1 and n+≤m≤1. The semiconductor material can also be Al_{X}Ga_{1-X}As with 0≤x≤1. The semiconductor layer sequence can contain dopants and additional components. For the sake of simplicity, however, only the essential components of the crystal lattice of the semiconductor layer sequence, i.e., Al, As, Ga, In, N or P, are given, even if these may be partially replaced and/or supplemented by small amounts of other substances.

The semiconductor layer sequence includes an active layer with at least one pn junction and/or with one or more quantum well structures. During operation of the semiconductor chip, electromagnetic radiation is generated in the active layer. A wavelength or the wavelength maximum is preferably in the ultraviolet, IR and/or visible spectral range, especially at wavelengths between 420 nm and 680 nm inclusive, for example between 440 nm and 480 nm inclusive.

According to at least one embodiment, the optoelectronic component comprises glass particles. The glass particles are stable to moisture. This means that the moisture-sensitive core in particular is protected against environmental influences, such as moisture or acid gases, and is not degraded.

According to at least one embodiment, the moisture-stable glass particles are arranged in the beam path of the semiconductor chip. In particular, the glass particles are embedded in a conversion element together with at least one phosphor in a matrix material.

The conversion element is especially arranged in the beam path of the semiconductor chip. The conversion element can be formed as a volume encapsulation. Alternatively, the conversion element can be formed as a layer. The glass particles and the phosphor can be embedded in a matrix material, for example silicone, polysiloxane, epoxy or an inorganic-organic hybrid material. The embedding can be homogeneous or inhomogeneous.

According to at least one embodiment, the conversion element comprises a matrix material. The matrix material may surround or contain the phosphor(s). The transparent matrix material can, for example, be a siloxane, epoxy resin, acrylate, methyl methacrylate, imide, carbonate, olefins, styrene, urethane or derivatives thereof in the form of monomers, oligomers or polymers and furthermore mixtures, copolymers or compounds therewith. For example, the matrix material may comprise or be an epoxy resin, polymethyl methacrylate (PMMA), polystyrene, polycarbonate, polyacrylate, polyurethane or a silicone resin such as polysiloxane or mixtures thereof.

According to at least one embodiment, the conversion element comprises at least one phosphor. The phosphor is configured to convert in particular the primary radiation emitted by the semiconductor chip into secondary radiation. For example, the semiconductor chip emits blue radiation and the phosphor at least partially or completely converts the emitted blue radiation into green or red radiation so that the total radiation emerging from the component is white mixed light.

According to at least one embodiment, the conversion element comprises more than one phosphor, for example two, three, four, five or six phosphors. The phosphors can be homogeneously distributed in the matrix material.

According to at least one embodiment, the conversion element is constructed as a multi-layer system. This can mean that the phosphor forms a first layer with the matrix material and a further layer can be arranged on top of this, which has the glass particles embedded in the matrix material or in another matrix material. The embedding can be done for example by dispersion.

The at least one phosphor is preferably selected from the following group:
Eu²⁺-doped nitrides such as (Ca,Sr)AlSiN₃:Eu²⁺,
Sr(Ca,Sr)Si₂Al₂N₆:Eu²⁺, (Sr,Ca)AlSiN₃*Si₂N₂O:Eu²⁺,
(Ca,Ba,Sr)₂Si₅N₈:Eu²⁺, (Sr,Ca)[LiAl₃N₄]:Eu²⁺;
garnets of the general system
(Gd,Lu,Tb,Y)₃(Al,Ga,D)₅(O,X)₁₂:RE where X=halide, N or divalent element, D=trivalent or tetravalent element and RE=rare earth metals such as Lu₃(Alₗ₋ₓGaₓ)₅O₁₂:Ce³⁺,
Y₃(Al₁₋ₓGaₓ)₅O₁₂:Ce³⁺;
Eu²⁺-doped sulfides such as (Ca,Sr,Ba)S:Eu²⁺;
Eu²⁺-doped SiONs such as (Ba,Sr,Ca)Si₂O₂N₂:Eu²⁺;
SiAlONs approximately from the system LiₓM_{y}Ln_{z}Si₁₂₋₍ₘ₊ₙ₎Al₍ₘ₊ₙ₎OₙN₁₆₋ₙ;
beta-SiAlONs from the system Si₆₋ₓAl_{z}O_{y}N_{8-y}:RE_{z} with RE=rare earth metals;
nitrido-orthosilicates like AE₂₋ₓ₋ₐREₓEuₐSiO₄₋ₓNₓ or
AE₂₋ₓ₋ₐREₓEuₐSi_{1-y}O_{4-x-2y}Nₓ with RE=rare earth metal and AE=alkaline earth metal or like (Ba,Sr,Ca,Mg)₂SiO₄:Eu²⁺;
chlorosilicates such as Ca₈Mg(SiO₄)₄Cl₂:Eu²⁺;
chlorophosphates such as (Sr,Ba,Ca,Mg)₁₀(PO₄)₆Cl₂:Eu²⁺;
BAM phosphors from the BaO—MgO—Al₂O₃ system such as BaMgAl₁₀O₁₇:Eu²⁺;
halophosphates such as M₅(PO₄)₃(Cl,F):(Eu²⁺,Sb²⁺,Mn²⁺);
SCAP phosphors such as (Sr,Ba,Ca)₅(PO₄)₃Cl:Eu²⁺;
alkaline earth aluminates such as AE₄Al₁₄O₂₅:Eu²⁺ with AE=Sr, Ba, Ca, Mg (alone or in combination).

In addition, so-called quantum dots can also be introduced as phosphors. Quantum dots in the form of nanocrystalline materials containing a group II-VI compound and/or a group III-V compound and/or a group IV-VI compound and/or metal nanocrystals are preferred. Furthermore, the phosphor may have a quantum well structure and be epitaxially grown.

According to at least one embodiment, the glass particles are used as filler. This means in particular that the glass particles are present in the matrix material in addition to the phosphor particles and either increase the filling level in the conversion layer (the filling level can be the ratio of particle volume fraction to matrix volume fraction), or increase the layer thickness of a conversion element with a fixed volume fraction of particles in the conversion element.

According to at least one embodiment, the glass particles are used as scattering particles. This can mean that the glass particles have a refractive index different from the refractive index of the matrix material and that they develop a desired scattering effect depending on the glass particle size and the refractive index contrast. This can be desired, for example, to adjust color via the angle of the component.

According to at least one embodiment, the glass particles are used as filter particles. This can mean here that the glass particles absorb at least part of the primary radiation emitted by the semiconductor chip and/or at least part of the secondary radiation emitted by the phosphor particles. This may be desirable, for example, in order to filter out blue light components in the LED spectrum in a semiconductor component whose goal is full conversion (as complete as possible conversion of the blue primary radiation by phosphor particles into green, yellow, orange or red secondary radiation) without having to drastically increase the amount of phosphor in the component and thus excessively reduce the efficiency of the component.

According to at least one embodiment, the moisture-stable glass particles comprise a moisture-sensitive core. In particular, the core is sensitive to environmental influences such as moisture. In other words, the core degrades in relation to environmental influences. The core comprises or consists of at least one glass material.

The glass material or the core may be selected from a group comprising silicate glass, borate glass and tellurite glass. Examples of this are the filter glass OG590 and RG610 from Schott (so-called tarnish glass) or R-60 from Hoya; especially in the case of filter glass it is also conceivable that the coating protects not only the glass base material but also or especially the coloring component in the glass from the effects of moisture, for example.

The glass material or the core can be selected from a group comprising silicate glass and subtypes, phosphate glass and subtypes, borate glass and subtypes, chalcogenide glass (sulphide, selenide, tellurite glass) and subtypes, halide glass and subtypes, mixed glass of the aforementioned types (for example oxynitride glass, borosilicate glass), organic glass and optical filter glass (annealing glass, ion-colored glass, pure base glass).

According to at least one embodiment, the moisture-sensitive core comprises an inorganic coating. The inorganic coating is moisture stable. This means in particular that it is resistant to environmental influences, especially moisture. In particular, the inorganic coating completely covers the moisture-sensitive core. The inorganic coating thus protects the core from degradation caused by environmental influences.

The inventors recognized that a barrier effect against environmental influences can be created by using coated glass particles, so that the glass particles are stable. In addition, the refractive index differences between the core and the matrix material and/or phosphor can be perfectly matched by the inorganic coating.

According to at least one embodiment, the inorganic coating has a thickness of maximum 3 nm. In particular, the inorganic coating has a thickness of 0.4 to 200 nm, especially 1 to 50 nm, especially 2 to 30 nm.

The inorganic coating can also consist of a monolayer. This means here that the inorganic coating is formed from a layer of one layer of an atom or molecule or a stoichiometric unit.

Alternatively, the inorganic coating can also be formed from a multi-layer system. For example, the inorganic coating can be produced by atomic layer deposition. A first layer with a thickness of 0.1 nm or more, for example, can be produced, even in the monolayer range. A second inorganic coating can then be applied to the first inorganic coating in the nanometer range. The material of the first inorganic coating can be the same or different from the material of the second inorganic coating. The second inorganic coating may be followed by other inorganic coatings which have the same or different material as the first and/or second coating.

According to at least one embodiment, the inorganic coating is selected from a group comprising or comprising oxides, oxynitrides or nitrides of one or more elements of the following group and combinations thereof: silicon, aluminium, titanium, zinc, indium, tin, niobium, tantalum, hafnium, zirconium, yttrium, germanium and combinations thereof. The materials shall not be restricted to these. Rather, other materials, especially those that can be processed by ALD, can be used, especially those that have a different refractive index compared to the moisture-sensitive core. In particular, the material of the inorganic coating has a different refractive index than the refractive index of the moisture-sensitive cores. The thickness of the coating can vary and can be precisely controlled by the above mentioned methods. For example, each inorganic coating may have a layer thickness of a few atoms, for example, of about 0.5 nm or more in the range of a few nm. This allows a robust component to be produced that has a high light output.

According to at least one embodiment, the glass particles are formed spherical, elliptical, rod-shaped or splinter-shaped. Alternatively, the glass particles can also have their natural crystal shape.

According to at least one embodiment, the inorganic coating is produced by means of chemical vapor deposition (CVD), plasma enhanced chemical vapor deposition (PECVD) or atomic layer deposition (ALD). The inorganic coating is applied to the moisture-sensitive core of the glass particles in such a way that the inorganic coating forms a moisture barrier. In particular, the inorganic coating is produced by ALD.

In order to produce a dense inorganic coating on the moisture-sensitive core, special reactor types, such as a fluidized bed reactor, a rotating cylindrical reactor, a flat bed reactor or other reactor types can be used in particular. In particular, at least the moisture-sensitive cores are moved during production and thus the inorganic coating can easily be applied to the entire surface of the moisture-sensitive core.

Especially when using ALD, the coating properties of the inorganic coating can be controlled very well and the inorganic coating can be produced with a high uniform, i.e., three-dimensional structure.

According to at least one embodiment, more than one inorganic coating, for example two or more, can be used with different materials. The other materials can improve the barrier effect against moisture and/or the refractive index adjustment.

According to at least one embodiment, the inorganic coating surrounds the core in a material and form-fit manner. This means in particular that the core is completely surrounded by the inorganic coating, so that it is resistant to environmental influences.

According to at least one embodiment, the glass particles are transparent to the radiation emitted by the semiconductor chip and/or the phosphor particles.

According to at least one embodiment, the glass particles are only partially transparent to the primary radiation emitted by the semiconductor chip and/or the secondary radiation emitted by the phosphor particles.

According to at least one embodiment, the glass particles are free of a phosphor. This means in particular that the core and/or the inorganic coating of the glass particles are free of a phosphor. In other words, the glass particles are not used for light conversion, but in particular exclusively as a filler, as scattering particles and/or as filter particles.

According to at least one embodiment, the core of the glass particles is present as a powder before the inorganic coating is applied.

According to at least one embodiment, the inorganic coating is applied by means of an atomic layer deposition (ALD) or by means of molecular layer deposition (MLD) process. Thus at least a first inorganic coating is produced by means of an ALD or MLD process. Although ALD and MLD processes are known in principle, such processes are used in connection with the production of encapsulation components in organic light-emitting diodes.

According to another embodiment, all inorganic coatings can be produced by means of ALD.

According to at least one embodiment, an electrically conductive or an electrically insulating material is applied by means of ALD or MLD. This can be, for example, an electrically conductive or electrically insulating oxide, especially metal oxide. For example, one or more materials selected from aluminium oxide (Al₂O₃), titanium oxide, in particular titanium dioxide (TiO₂), silicon oxide (SiOₓ), aluminium zinc oxide, zinc oxide (ZnOₓ), indium tin oxide, zirconium oxide (ZrOₓ), hafnium oxide (HfOₓ), niobium oxide, in particular niobium pentoxide (Nb₂O₅) and tantalum oxide, in particular tantalum pentoxide (Ta₂O₅) can be applied.

In addition, a nitride such as silicon nitride (SiₓN_{y}), aluminium nitride (AlN_{X}), titanium nitride (TiNₓ), or germanium nitride (GeₓN_{y}) may also be possible.

Oxides, oxynitrides or nitrides can be selected from one or more elements of the following group: silicon, aluminium, titanium, zinc, indium, tin, niobium, tantalum, hafnium, zirconium, yttrium, germanium or combinations thereof.

With such materials it may be possible that they cannot be deposited by standard processes, such as vacuum evaporation or liquid processing, or that they cannot be deposited in sufficient quality. In principle it is possible to apply such materials by sputtering, but this process is disadvantageous for the production of a moisture-resistant glass particle.

According to another embodiment, the atomic layer deposition process or the molecular layer deposition process is carried out at a temperature of less than or equal to 100° C. Preference can thus be given to materials that can be applied by means of a so-called low-temperature ALD or MLD. Exemplary starting materials are given below, whereby exemplary process temperatures are given in brackets for each of the given materials, together with other starting materials for the formation of the layer materials given afterwards:
Trimethylaluminium (H₂O; 33° C., 42° C.; Al₂O₃)
Trimethylaluminum (O₃; room temperature; Al₂O₃)
Trimethylaluminum (O₂ plasma; room temperature; Al₂O₃)
Hf[N(Me₂)]₄ (H₂O; 90° C.; HfO₂)
Tetrakis(dimethylamino)tin (H₂O₂; 50° C.; SnO₂)
C₁₂H₂₆N₂Sn (H₂O₂; 50° C.; SnOₓ)
TaCl₅ (H₂O; 80° C.; Ta₂O₅)
Ta[N(CH₃)₂]₅ (O₂ plasma; 100° C.; Ta₂O₅)
Ti[OCH(CH₃)]₄ (H₂O; 35° C.; TiO₂)
TiCl₄ (H₂O; 100° C.; TiO₂)
Zn(CH₂CH₃)₂ (H₂O; 60° C.; ZnO)
Zn(CH₂CH₃)₂ (H₂O₂; room temperature; ZnO)
(Zr(N(CH₃)₂)₄)₂ (H₂O; 80° C.; ZrO₂)

According to another embodiment, the inorganic coating forms a closed film, which in particular has some atomic layers and is produced by means of ALD or MLD.

Embodiments further provide a process for producing an optoelectronic component. In particular, the process described here is used to produce the optoelectronic component described here. All definitions of the optoelectronic component also apply to the process and vice versa.

In at least one embodiment, the process for producing an optoelectronic component comprises the steps
A) providing a semiconductor chip capable of emitting radiation,
B) Generation of moisture-stable glass particles, which are arranged in the beam path of the semiconductor chip and are used as filler, scattering particles and/or filter particles, for this purpose,
B1) providing moisture sensitive cores of a glass material,
B2) Coating the moisture-sensitive cores with a moisture-stable inorganic coating by means of ALD, so that the inorganic coating completely covers the cores with an inorganic coating.

In particular, step B) follows step A). In particular, steps B1) and B2) are partial steps of step B).

According to at least one embodiment, the inorganic coating is applied in a flat bed reactor.

According to at least one embodiment, the inorganic coating takes place in a fluidized bed reactor.

According to at least one embodiment, the following precursor materials or combinations thereof are used to produce the inorganic coating: trimethylaluminium, trimethylaluminium, Hf[N(Me₂)]₄, tetrakis(dimethylamino)tin, C₁₂H₂₆N₂Sn, TaCl₅, Ta[N(CH₃)₂]₅, Ti[OCH(CH₃)]₄, TiCl₄, Zn(CH₂CH₃)₂, Zn(CH₂CH₃)₂, (Zr(N(CH₃)₂)₄)₂.

The inventors recognized that the use of the coated glass particles can improve the moisture stability of these glass particles. Thus, these glass particles can be used in a variety of applications compared to conventional glass particles, such as soda glass.

In addition, the light extraction or brightness can be improved due to the refractive index adjustment of the inorganic coating between the glass particles and the inorganic coating. For example, the refractive index of the core is about 1.5 for lime-sodium bicarbonate-silica glass, about 1.47 for borosilicate glass and about 1.5 for aluminosilicate glass. The inorganic coating can be sapphire with a refractive index of 1.77 or silicon oxide with a refractive index of 1.47. The surrounding silicone as matrix material has a refractive index of 1.41 to 1.56. The refractive index can be adjusted by using several inorganic coatings.

The coating material for the inorganic coating can be chosen differently for each application. Thus, the barrier effect and the scattering effect can be tailored. The following values are for bulk material, for (very) thin layers the values may differ.

| | Refractive index n |
|---|---|
| titanium dioxide | 2.45 |
| zirconium oxide | 2.11 |
| aluminium oxide (sapphire) | 1.77 |
| silicon dioxide | 1.47 |
| Siliziumnitrid | 1.98 |
| zinc oxide | 1.93 |
| tantalum oxide | 2.15 |
| magnesium oxide | 1.71 |
| hafnium oxide | 2.08 |
| aluminium nitride | 2.15 |

By using the coating described here, the flowability of the glass particle powder can be improved by adjusting the electrostatic surface charge.

In addition, toxic glass particles, such as lead glasses, can be encapsulated by the inorganic coating, thus reducing the health risk during material processing.

By treating individual glass particles at powder level, different particles can be coated under optimal process conditions and then combined to form mixtures of several optimally and differently coated particles.

In addition, a stepwise reduction or increase of the refractive index of the core of the glass particles can be adapted to the matrix material via the inorganic coating, thus influencing the scattering profile of the glass particles in the conversion element. The scattering of the glass particles can be reduced or eliminated or the scattering properties can be increased.

### BRIEF DESCRIPTION OF THE DRAWINGS

Further advantages, advantageous embodiment and further developments result from the exemplary embodiments described below in connection with the figures.

FIG. 1A shows a moisture-stable glass particle according to an embodiment;

FIG. 1B shows a moisture-stable glass particle according to an embodiment;

FIG. 2A shows an optoelectronic component according to an embodiment;

FIG. 2B shows an optoelectronic component according to an embodiment;

FIG. 3 shows the production of a moisture-stable glass particle according to an embodiment in a fluidized bed reactor;

FIG. 4 shows the production of a moisture-stable glass particle according to an embodiment in a flat-bed reactor; and

FIG. 5 shows the production of a moisture-stable glass particle according to an embodiment by atomic layer deposition.

### DETAILED DESCRIPTION OF ILLUSTRATIVE EMBODIMENTS

In the exemplary embodiments and figures, identical, similar or similarly acting elements may each be provided with the same reference signs. The depicted elements and their proportions among each other are not to be regarded as true to scale. Rather, individual elements, such as layers, components, components and areas, can be displayed in an exaggeratedly large format for better representability and/or better understanding.

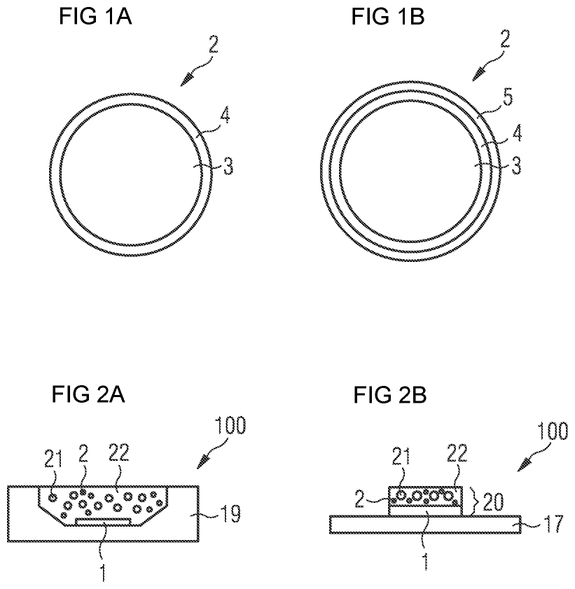

FIG. 1A shows a schematic side view of a moisture-stable glass particle according to an embodiment. The moisture-stable glass particle 2 is especially arranged in the beam path of a semiconductor chip 1 of an optoelectronic component 100. The moisture-stable glass particle 2 comprises a moisture-sensitive core 3. The moisture-sensitive core 3 can consist of a glass material, for example, a silicate glass. The core 3 can have at least one moisture-stable inorganic coating 4, for example of aluminium oxide or titanium dioxide. In particular, the inorganic coating 4 completely covers the moisture-sensitive core 3.

As shown in FIG. 1B, the moisture-stable glass particle 2 comprises a second inorganic coating 5. The second inorganic coating 5 can be formed from the same material or from a different material than the first inorganic coating 4. The second inorganic coating 5 completely covers the first inorganic coating 4. The respective inorganic coating 4, 5 can have a maximum thickness of 3 nm. In particular, the inorganic coatings 4, 5 are produced by means of atomic layer deposition. Each layer can have, for example, a layer thickness of a few nanometers, for example 0.1 nm.

FIG. 2A shows a schematic side view of an optoelectronic component 100 according to an embodiment. The optoelectronic component 100 in FIG. 2A comprises a package 19. The package 19 may, for example, be formed from a silicone material, EMC (epoxy mold compound), SMC (silicone mold compound) or a thermoplastic such as, for example PPA (polyphthalamide) or PCT (polycyclohexylene dimethylene terephthalate), or may contain it as a matrix material. A semiconductor chip 1 can be arranged in the recess of the housing 19. The semiconductor chip 1 is configured to emit radiation, especially from the blue spectral range. In the recess of the housing 19, a conversion element 20 can be formed as an encapsulation. The conversion element 20 can have a matrix material 22, for example silicone, in which at least one phosphor 21 or other particles are embedded. In addition, the matrix material 22 may also have embedded the moisture-stable glass particles 2. The embedding can be homogeneous or inhomogeneous. The homogeneous embedding of the glass particles 2 and phosphors 21 in the matrix material 22 is shown here. Alternatively, components without conversion particles can be used. In this case, the glass particles can be used for CTE adjustment (for example to the substrate).

FIG. 2B shows a schematic side view of an optoelectronic component 100 according to an embodiment. FIG. 2B differs from FIG. 2A in that the conversion element 20 is shaped as a layer. In particular, the conversion element 20 is shaped as a platelet which is applied, for example glued, to the chip surface 1 in the so-called pick and place process. The conversion element 20 can have a matrix material 22 in which a phosphor 21 and the glass particles 2 are embedded. The conversion element 20 and the semiconductor chip 1 can be arranged on a substrate 17, for example on a sapphire substrate.

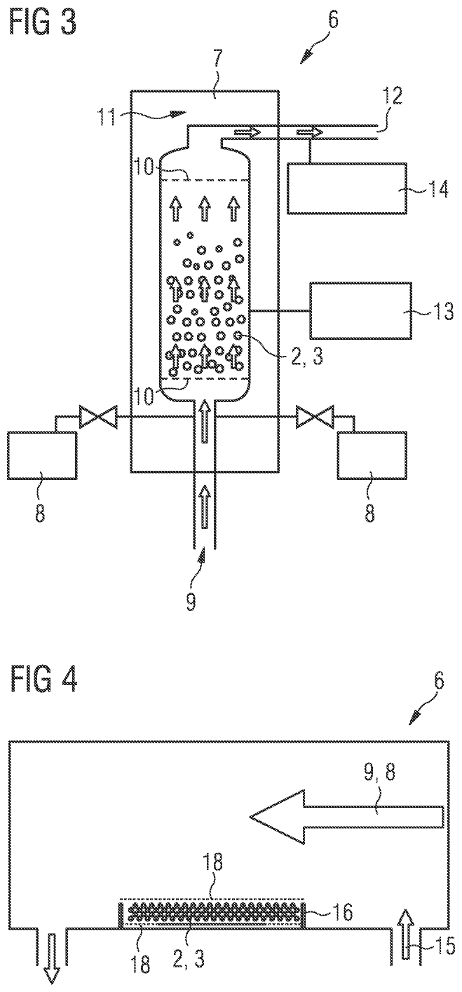

FIG. 3 shows a schematic side view of a process for producing glass particles according to an embodiment. Here, the glass particles are produced by means of ALD or CVD. The reactor used is a fluidized bed reactor. At least the core 3 of the glass particles is formed in powder form. The glass particles 2 or the moisture-sensitive cores 3 are filled into a reactor of a vacuum chamber 7. The glass particles 2 and/or cores 3 are especially powdery.

A carrier gas such as nitrogen, hydrogen or argon is then added. This moves the cores 3 and/or glass particles 2 and the precursor materials, such as trimethylaluminum, TMA, and water 8 can be added during the respective process steps. The moisture-sensitive cores 3 are coated with the inorganic coating 4. Residual or unused gases 12 are removed, the residual gases can optionally be analyzed in a residual gas analyzer 14. By means of an additional mechanical vibration 13 in the reactor, the inorganic coating 4, in particular, can be made homogeneous.

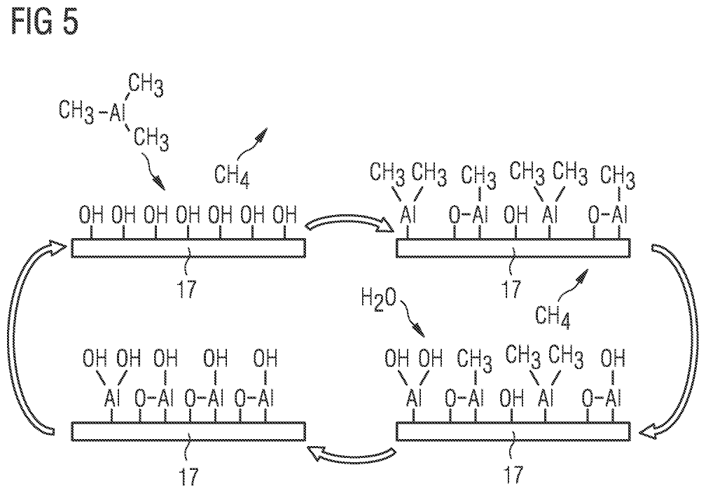

FIG. 4 shows a process for producing an optoelectronic component according to an embodiment. Here the coated glass particles 2 are produced by means of a flat bed reactor. The coating is done by means of ALD. Here the moisture-sensitive cores 3 are present as powder in a “bed”. They are enclosed or fixed, for example, by a filter paper 18, whereby the precursor materials and, if necessary, an additional carrier gas and the purge gas are introduced via an inlet 15. The moisture-sensitive cores 3 are coated step by step with the moisture-stable inorganic coating 4.

FIG. 5 shows a process for producing an optoelectronic component according to an embodiment. Here the coating by means of ALD, in particular by means of trimethylaluminium, TMA, as well as water on a surface is shown step by step. A substrate 17 has hydroxy groups on its surface. The added trimethylaluminium reacts with the hydroxy groups of the substrate surface, as a by-product methane is split off. At the end of this step, in the ideal case shown here, the entire surface is covered with methyl groups. This is followed by a rinsing step to remove the excess TMA from the coating chamber. Water is then added, the methyl units then being replaced by hydroxy groups with elimination of methane to form an Al₂O₃ layer. The surface thus formed is again hydroxy-terminated. After a further rinsing step to remove methane and excess water, this cycle can be continued again with the TMA feed. Thus an inorganic coating of aluminium oxide can be produced step by step.

For other coating materials, the deposition by means of ALD can be carried out analogously using the respective precursors.

The exemplary embodiments described in connection with the figures and their features can also be combined with each other according to further exemplary embodiments, even if such combinations are not explicitly described or shown in the figures. Furthermore, the exemplary embodiments described in connection with the figures may have additional or alternative features as described in the general part.

The invention is not limited by the description based on the exemplary embodiments on these. Rather, the invention comprises any new feature as well as any combination of features, which in particular includes any combination of features in the patent claims, even if such feature or combination is not explicitly stated in the patent claims or exemplary embodiments.

1-16. (canceled)

17. An optoelectronic component comprising:
a semiconductor chip configured to emit radiation; and
moisture-stable glass particles arranged in a beam path of the semiconductor chip, the moisture-stable glass particles being filler, scattering particles and/or filter particles,
wherein each of the moisture-stable glass particles comprises a moisture-sensitive core of a glass material, and
wherein the core is covered with at least one moisture-stable inorganic coating.

18. The optoelectronic component according to claim 17, wherein the inorganic coating has a thickness of 0.4 nm to 200 nm inclusive.

19. The optoelectronic component according to claim 17, wherein the core is selected from the group consisting of silicate glass, phosphate glass, borate glass, chalcogenide glass, halide glass, mixed glass of the aforementioned glasses, organic glass and optical filter glass.

20. The optoelectronic component according to claim 17, wherein the inorganic coating is selected from a group consisting of oxides, oxynitrides and nitrides of silicon, aluminum, titanium, zinc, indium, tin, niobium, tantalum, hafnium, zirconium, yttrium, or germanium.

21. The optoelectronic component according to claim 17, wherein the glass particles have a spherical form, an elliptical rod-shaped form or a splinter-shaped form.

22. The optoelectronic component according to claim 17, wherein the inorganic coating is produced by chemical vapour deposition (CVD), plasma enhanced chemical vapour deposition (PECVD) or atomic layer deposition (ALD).

23. The optoelectronic component according to claim 17, wherein the inorganic coating surrounds the core in a material and form-fit manner.

24. The optoelectronic component according to claim 17, wherein the glass particles are embedded in a conversion element together with at least one phosphor in a matrix material.

25. The optoelectronic component according to claim 17, wherein the glass particles are transparent to the radiation and radiation emitted from phosphor particles.

26. The optoelectronic component according to claim 17, wherein the glass particles are only partially transparent to the radiation and/or radiation emitted by phosphor particles.

27. The optoelectronic component according to claim 17, wherein the glass particles are free from a phosphor.

28. The optoelectronic component according to claim 17, wherein the core of the glass particles is present as a powder prior to applying the inorganic coating.

29. A method for producing an optoelectronic component, the method comprising:
providing a semiconductor chip capable of emitting radiation;
generating moisture-stable glass particles; and
arranging the moisture-stable glass particles in a beam path of the semiconductor chip, wherein the moisture-stable glass particles are filler, scattering particles and/or filter particles, and wherein the moisture-stable glass particles are produced by:
providing moisture-sensitive cores of a glass material, and
coating the moisture-sensitive cores with a moisture-stable inorganic coating by an atomic layer deposition (ALD) so that the inorganic coating completely covers the cores with an inorganic coating.

30. The method according to claim 29, wherein the inorganic coating is carried out in a flat bed reactor.

31. The method according to claim 29, wherein the inorganic coating takes place in a fluidized bed reactor.

32. The method according to claim 29, wherein the following precursor materials are used to produce the inorganic coating: trimethylaluminium, trimethylaluminium, Hf[N(Me₂)]₄, tetrakis(dimethylamino)tin, C₁₂H₂₆N₂Sn, TaCl₅, Ta[N(CH₃)₂]₅, Ti[OCH(CH₃)]₄, TiCl₄, Zn(CH₂CH₃)₂, Zn(CH₂CH₃)₂, or (Zr(N(CH₃)₂)₄)₂.
